(19) United States
(12) Patent Application Publication
(10) Pub. No.: US 2026/0059697 A1
(43) Pub. Date: Feb. 26, 2026

(54) CENTRALIZED ADMINISTRATION OF LIQUID COOLING WITH QUICK DISCONNECTS

(71) Applicant: DELL PRODUCTS L.P., Round Rock, TX (US)

(72) Inventors: Timothy M. Lambert, Austin, TX (US); Sandor Farkas, Round Rock, TX (US); Kevin Mundt, Livingston, TX (US)

(21) Appl. No.: 18/810,902

(22) Filed: Aug. 21, 2024

(51) Int. Cl. H05K 7/20; G06F 1/20

(52) U.S. Cl. CPC H05K 7/20272; G06F 1/206; H05K 7/20781; H05K 7/20836; G06F 2200/201

(57) ABSTRACT

An apparatus includes N motor circuits, a fan-out circuit, and a first administration circuit. The N motor circuits are configured to control disconnection of N hoses that transport cooling liquid to sites in a computing system. The fanout circuit is configured to communicate with the N motor circuits. The first administration circuit is configured to administer cooling services for the computing system by performing first administration tasks on the N motor circuits under a first policy via the fanout circuit based on a detected leak associated with one of the N hoses.

### FIELD OF THE DISCLOSURE

This disclosure generally relates to liquid cooling, and more particularly relates to centralized administration of liquid cooling systems.

### BACKGROUND

As the value and use of information continues to increase, individuals and businesses seek additional ways to process, store, and display information. One option is an information handling system. An information handling system generally processes, compiles, stores, communicates and/or display information or data for business, personal, or other purposes. Because technology and information handling needs and requirements may vary between different applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, reservations, enterprise data storage, or global communications. In addition, information handling systems may include a variety of hardware and software resources that may be configured to process, store, display, and communicate information and may include one or more computer systems, data storage systems, and networking systems.

As technology becomes advanced, information handling systems become increasingly complex. To meet demands for high performance, information handling systems are packed with a large amount of semiconductor chips, computing circuits, and many peripheral and interfacing elements. Such systems typically consume a lot of power and generate excessive heat that may cause diminished quality and even damage to the systems. To reduce heat, cooling techniques have been developed. Among various cooling techniques, liquid cooling has been increasingly popular due to its energy efficiency, performance effectiveness, and low cost. Liquid cooling techniques, however, may create problems such as leaks. Leak control and management, therefore, is useful to maintain the integrity of the cooling system in high computing environments such as complex information handling systems, artificial intelligence (AI) platforms, and data centers.

### SUMMARY

An apparatus includes N motor circuits, a fan-out circuit, and a first administration circuit. The N motor circuits are configured to control disconnection of N hoses that transport cooling liquid to sites in a computing system. The fanout circuit is configured to communicate with the N motor circuits. The first administration circuit is configured to administer cooling services for the computing system by performing first administration tasks on the N motor circuits under a first policy via the fanout circuit based on a detected leak associated with one of the N hoses.

### BRIEF DESCRIPTION OF THE DRAWINGS

It will be appreciated that for simplicity and clarity of illustration, elements illustrated in the Figures have not necessarily been drawn to scale. For example, the dimensions of some of the elements are exaggerated relative to other elements. Embodiments incorporating teachings of the present disclosure are shown and described with respect to the drawings presented herein, in which:

FIG. 1 is a block diagram illustrating a system according to an embodiment of the present disclosure;

FIG. 2 is a diagram illustrating a centralized administrator according to an embodiment of the present disclosure;

FIG. 3 is a diagram illustrating a motor circuit according to an embodiment of the present disclosure;

FIG. 4 is a diagram illustrating a fan-out circuit according to an embodiment of the present disclosure;

FIG. 5 is a diagram illustrating a first administration circuit according to an embodiment of the present disclosure;

FIG. 6 is a diagram illustrating a discovery task according to an embodiment of the present disclosure;

FIG. 7 is a diagram illustrating a motor movement for disconnection according to an embodiment of the present disclosure;

FIG. 8 is a flowchart illustrating a process to perform quick disconnection according to an embodiment of the present disclosure;

FIG. 9 is a diagram illustrating a motor movement for self-test according to an embodiment of the present disclosure;

FIG. 10 is a flowchart illustrating a process to perform self-test according to an embodiment of the present disclosure;

FIG. 11 is a diagram illustrating second administration tasks according to an embodiment of the present disclosure;

FIG. 12 is a diagram illustrating a combination of the motor circuit and the hose assembly according to an embodiment of the present disclosure;

FIG. 13 is a diagram illustrating a hose with an embedded wire according to an embodiment of the present disclosure;

FIG. 14 is a diagram illustrating an information handling system according to an embodiment of the present disclosure.

The use of the same reference symbols in different drawings indicates similar or identical items.

### DETAILED DESCRIPTION OF DRAWINGS

The following description in combination with the Figures is provided to assist in understanding the teachings disclosed herein. The following discussion will focus on specific implementations and embodiments of the teachings. This focus is provided to assist in describing the teachings, and should not be interpreted as a limitation on the scope or applicability of the teachings. However, other teachings can certainly be used in this application. The teachings can also be used in other applications, and with several different types of architectures, such as distributed computing architectures, client/server architectures, or middleware server architectures and associated resources.

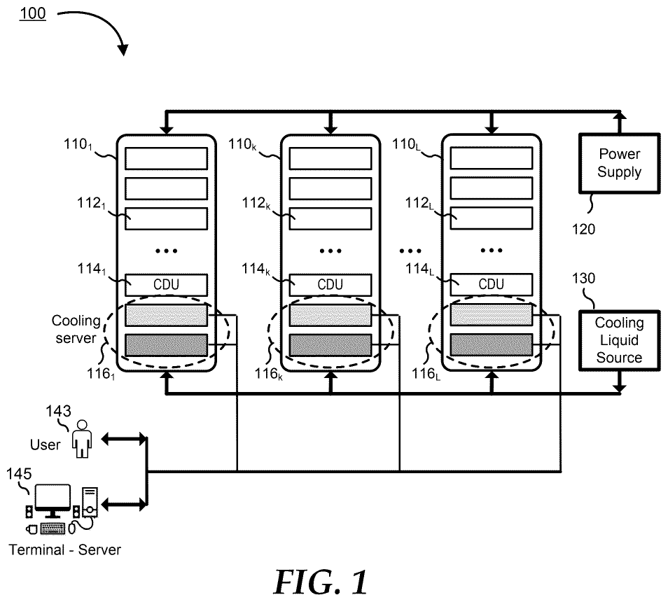

FIG. 1 is a block diagram illustrating a system 100 according to an embodiment of the present disclosure. The system 100 may be a multiprocessor computer system, a high performance computing (HPC) system, a large network center, a cluster of servers, a data center, an artificial intelligence (AI) system, edge computing, cloud computing, network servers, or any large electronic systems with high power consumption. The system 100 typically employs thousands of semiconductor devices such as central processing units (CPUs), graphical processing units (GPUs), and memory chips. The system 100 may include L rack, or rack-mounted, servers 110ₖ's, where k=1, . . . , L, a power supply 120, and a cooling liquid source 130. L is a positive integer with a value depending on the configuration of the system 100. The system 100 may include more or less than the above components. In the following, the subscript index k may be dropped for clarity.

The L rack servers 110ₖ's may be located in a single room, in several rooms, or scattered throughout a building, on the same floor or on different floors. The system 100 shown in FIG. 1 may have identical L rack servers 110ₖ's for illustrative purposes only. They may be the same or have different configurations. They may be part of clusters of processors in a highly parallel system or they may be established for specific applications such as medical, scientific research, or business enterprise. As an example, a server may be dedicated to intensive computing, another may serve to store data, yet another may focus on graphical display and animation. They may work as standalone subsystems or connected to one another via a local area network (LAN) or wide area network (WAN). The L rack servers 110ₖ's represent an example of an HPC system. The system 100 may include components that are packaged or assembled in any convenient format, and not necessarily to be mounted on racks, slots, or bays. The L rack servers 110ₖ's typically consume a large amount of power during active periods.

Because of this high power consumption, the L rack servers 110ₖ's generate an excessive amount of heat. Accordingly, a cooling technique is employed to cool the system and to prevent overheating that may cause performance degradation or damage to the system. In one embodiment, the cooling technique used in the system 100 is liquid cooling.

Each of the L rack servers 110ₖ's includes a number of servers 112ⱼ's where j=1, . . ., M (M is a positive integer having a predetermined value), a cooling distribution unit (CDU) 114ₖ and a cooling server 116ₖ. The servers 112ⱼ's are mounted on slots in the rack or cabinet. In this illustrative example, a server is typically designed for continuous and heavy use. Each server may be populated with electronic devices such as CPUs, memories, storage, and peripheral devices. They may also include network switches, cable management systems, and appropriate mounting hardware.

The CDU 114ₖ distributes coolant throughout the rack server 110ₖ. It may include a pumping mechanism to circulate the coolant to the heat-generating components or cold plates placed on top of CPUs or GPUs. The CDU 114ₖ may operate together with coolant distribution manifolds (CDMs). The CDMs are distribution pipes that supply coolant to each server and collect the hotter coolant back to the CDU. Flexible hoses are used to carry the cooler liquid to the individual server at the ingress to the various sites on the server and return the hotter liquid to the associated CDM at the egress. These hoses are connected through various connectors and valves. In one embodiment, the connectors include automated quick disconnectors which allow quick and automatic disconnection without manual intervention.

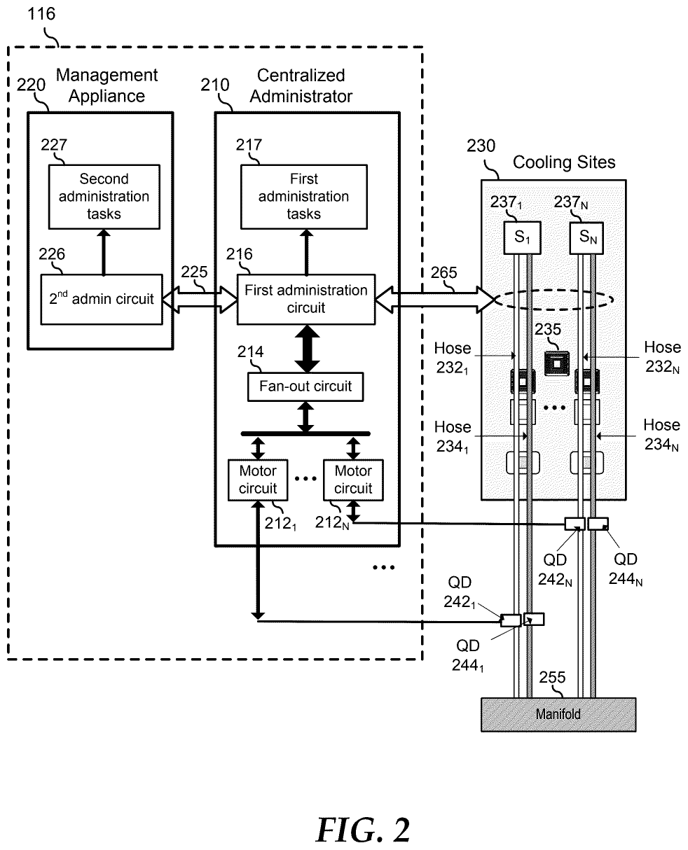

The cooling server 116ₖ includes circuits that perform administration of the cooling policies and implementations. The administration includes the central control, management, and regulation of various components, subsystems, or system in the system 100. The cooling server 116ₖ will be described further in the following with reference to FIG. 2. The cooling server 116ₖ may interact with a user 143 and/or a terminal or server 145. The user 143 may be any individual or entity responsible for the administration of the individual server in the L rack servers 110ₖ's or the system 100. The user 143 may receive status reports or alerts from the cooling server 116ₖ and respond with commands or instructions to the cooling server 116_{k.} The terminal or server 145 may include a processing circuit, software, or an application that has been designed to automatically respond to reports or alerts from the cooling server 116_{k.}

The power supply 120 provides power to the L rack servers 110ₖ's in addition to other power needs for the facilities including lighting, cooling (e.g., air-conditioning), network load. The power supply 120 may include a typical power infrastructure including transformers, power distribution units (PDUs), power breakers, uninterruptible power supplies (UPSes), and backup generators.

The cooling liquid source 130 may include any suitable sources for liquid cooling including water and dielectric fluids. It may include coolant distribution units (CDUs), liquid cooled racks, indoor chilled water storage, and pumps. The cooling type may be direct-to-chip cooling, immersion cooling, and rear-door liquid cooling. In one embodiment, the system 100 utilize the direct-to-chip cooling technique in which the cooling mechanisms are applied directly to the heat-generating components such as CPUs, GPUs, and memory chips. The cooling liquid source 130 delivers the coolant to each of the L rack servers 110ₖ's via the CDU 114ₖ's and CDMs.

FIG. 2 is a diagram illustrating the cooling server 116 according to an embodiment of the present disclosure. For clarity, the index subscript k is dropped. The cooling server 116 may include a centralized administrator 210 and a management appliance 220. The cooling server 116 interacts with cooling sites 230 in performing its functions. The cooling sites 230 may represent any sites, regions, or areas that receive cooling as part of the cooling system in the rack server 110. The cooling sites 230 may be collocated with the cooling server 116 or located anywhere in the rack server 110. The components in the cooling server 116 communicate with one another via various bus interfaces (including serial and parallel interfaces) and communication protocols. The communication may be unidirectional or bidirectional. In one embodiment, the bus interfaces or communication protocols are standardized to conform with industry standards to facilitate expansion and/or maintain compatibility among devices and components. Examples of these bus interfaces and communication protocols include the Universal Serial Bus (USB). Other bus interfaces may be employed such as Enhanced Serial Peripheral Interface (eSPI), Universal Asynchronous, Receiver/Transmitter (UART), I2C (two-wire serial communication protocol), or any other communication interfaces.

The centralized administrator 210 is configured or designed to administer the entire rack server 110. It may operate, control, manage, supervise, govern, and orchestrate various components in the system to achieve objectives stated in the cooling policies. The centralized administrator 210 may include components implemented as electrical circuits and electro-mechanical circuits. It may include N motor circuits 212ₖ's (k=1, . . ., N), a fan-out circuit 214, and a first administration circuit 216. N is a positive integer. Its value depends on the overall configuration of the rack server 110. The centralized administrator 210 may include more or less than the above components.

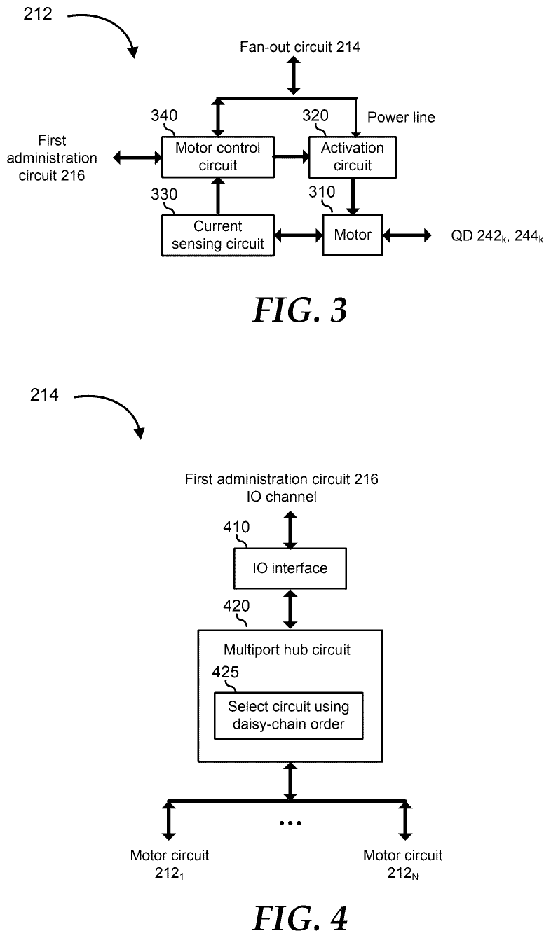

The N motor circuits 212ₖ's are configured or designed to control disconnection of N hoses that transport cooling liquid to sites in a computing system. The N hoses are hoses that carry cooling liquid to and from the cooling sites 230. The N motor circuits 212ₖ's may be located remotely or locally to the N hoses. In one embodiment, the N motor circuits 212ₖ's are placed locally to, or directly on, the quick disconnects at the N hoses so that they can operate directly on the quick disconnects for an automatic disconnection of the associated hose from the hose loop when there is a leak. The motor circuit 212 is further described in FIG. 3.

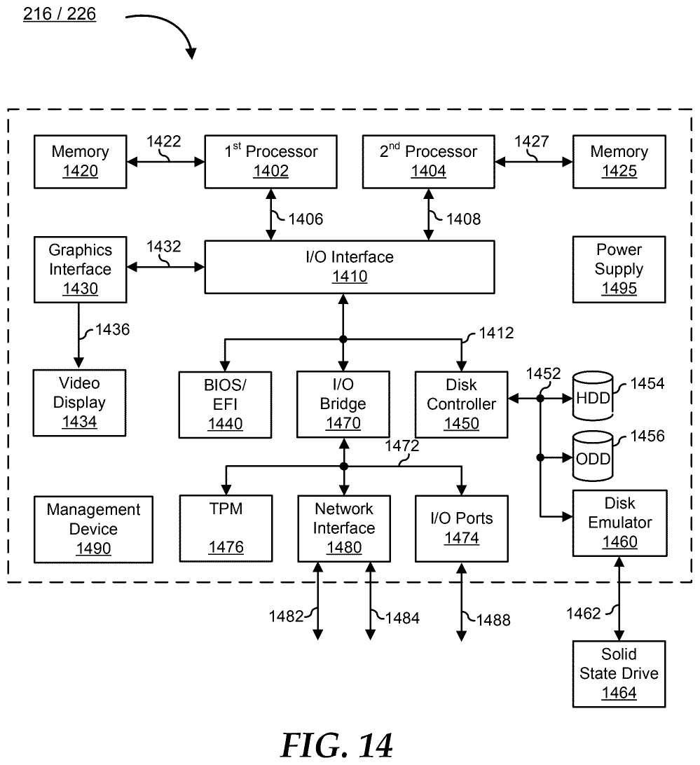

The fanout circuit 214 is configured to communicate with the N motor circuits 212ₖ's to send commands to, or receive status conditions from, each of the N motor circuits 212ₖ's. The fanout circuit 214 allows a single centralized administration circuit like the first administration circuit 216 to control and manage the N motor circuits 212ₖ's dispersed throughout the rack server 110. The fan-out circuit 214 is further described in FIG. 4 The first administration circuit 216 is configured to administer cooling services for the rack server 110. It performs functions similar to those of an information handling system or a baseboard management controller (BMC). It typically has a programmable processor that can execute instructions or programs stored in memories. The first administration circuit 216 is described in FIG. 14. Centralizing the administration of the cooling policies allows an efficient utilization of resources, maintains a consistent cooling implementation across the rack server 110, orchestrates activities of several components across the system, and avoids errors or conflicts. The cooling policies are policies or rules that are developed as guidelines to implement procedures in responding to various operating conditions of the rack server 110 such as fault conditions. For example, a priority policy may establish a priority of service when there are multiple requests for service. A yield policy may yield the control or management of the motor circuits 212ₖ's to the management appliance 220 when the management appliance 220 intervenes. The cooling policies may be programmed in the application that runs the first administration circuit 216.

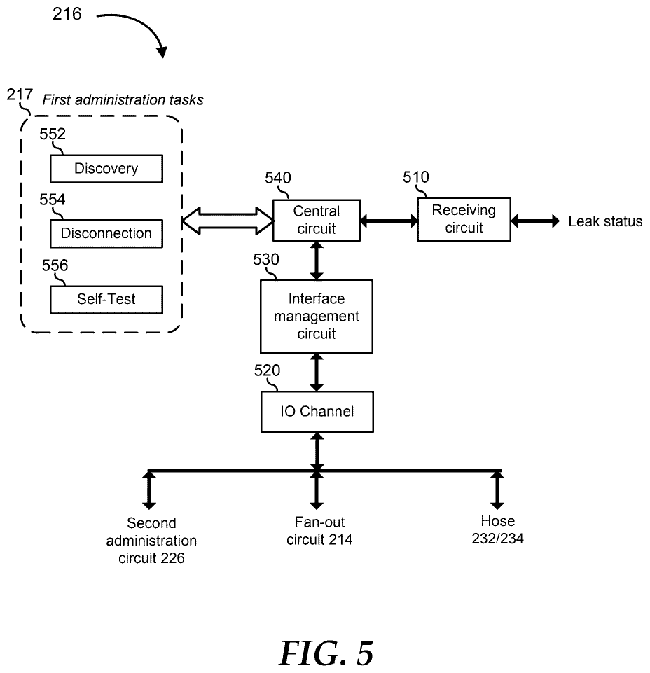

The first administration circuit 216 administers the cooling services by performing first administration tasks 217 on the N motor circuits 212ₖ's under a first policy via the fanout circuit 214 based on an operating condition such as a detected leak associated with one of the N hoses. The first policy may be any policy from the above cooling policies as adopted by the first administration circuit 216. The first administration tasks 217 include tasks that may be performed as part of a procedure to implement the first policy. The first administration circuit 216 and the first administration tasks 217 will be described further in FIG. 5.

The management appliance 220 operates together with the centralized administration circuit 210 to ensure robust operations thanks to redundancy. It has similar responsibilities as the centralized administrator 210. It provides reliability and fault-tolerance to the system by operating separately and independently from the centralized administrator 210. It communicates with the first administration 216 via a bus 225. The bus 225 may be a USB and a communication interface following any suitable communication protocol.

The management appliance 220 may be optional. The management appliance 220 acts as an additional component to administer the cooling services. The management appliance 220 may include a second administration circuit 226 which is configured to communicate with the first administration circuit 216 and perform second administration tasks 227 under a second policy.

The second policy may or may not be the same as the first policy. In one embodiment, when used, the management appliance 220 may have a higher authority than the centralized administrator 210. For example, it may override the centralized administrator 210 when it determines that the centralized administrator 210 does not satisfy some performance metrics. In one embodiment, the management appliance 220 may function as a secondary processing circuit as part of a fault-tolerant configuration.

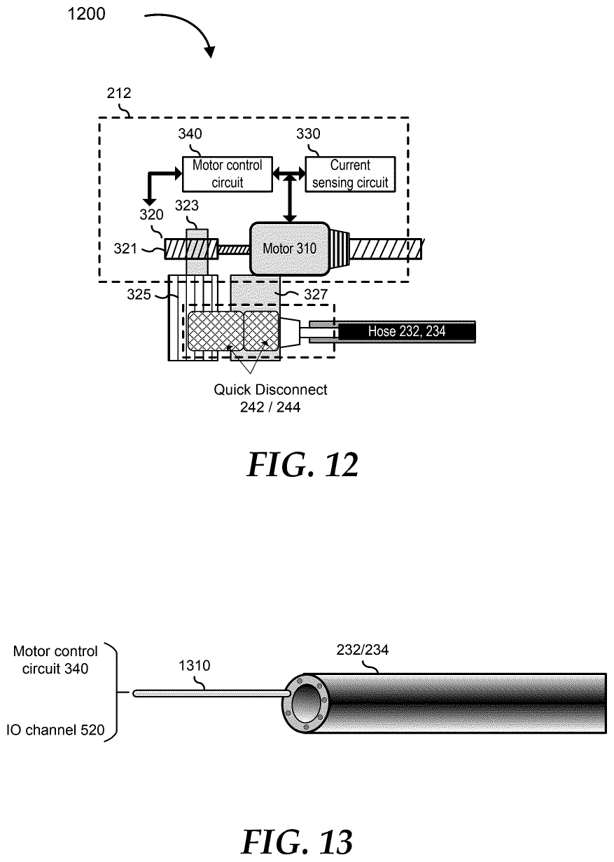

The cooling sites 230 include N cool (forward) hoses 232ₖ's and N hot (return) hoses 234ₖ's, k=1, . . . , N. The N cool hoses 232ₖ's carry cool liquid through the components 235 populated in the rack server 110 and to cold plates Sₖ's 237ₖ's and return the hot liquid through the respective N hot hoses 234ₖ's. Each of the hoses 232ₖ's and 234ₖ's may include a communication wire to allows source-and-destination discovery over a bus 265 that connected to the first administration circuit 216. The communication wire will be further described in FIG. 13. The cool hoses 232ₖ's may be coupled with quick disconnects (QDs) 242ₖ's at the ingresses. The hot hoses may be coupled with QD 244ₖ's at the egresses. In one embodiment, the QD 244ₖ's may be replaced by check valves and plugs to provide a lower cost alternative. The motor circuits 212ₖ's are connected to the respective QD 242ₖ's to automatically actuate quick disconnection to eject the respective hose from the cooling loop when there is a fault in the cooling loop such as a leakage. In one embodiment, the motor circuits 212ₖ's are placed directly on the respective QD 242ₖ's to effectuate the needed disconnection. Such a configuration will be described in FIG. 12.

FIG. 3 is a diagram illustrating the motor circuit 212 according to an embodiment of the present disclosure. For clarity, the subscript k is dropped. The motor circuit 212 may include a motor 310, an activation circuit 320, a current sensing circuit 330, and a motor control circuit 340.

The motor 310 is configured or designed to actuate the corresponding QD 242 (shown in FIG. 2) that is coupled to the respective hose 232. The actuation is carried out based on a leak status such as when a leak detector reports a leak in the hose loop. The actuation is a mechanical action that operates on the QD 242 to perform a disconnection. The motor 310 is a direct current (DC) motor having a small size comparable with the QD 242. In one embodiment, the motor 310 is a gear motor which has a gearbox to increase the torque and reduce the speed. The operation of the motor 310 on the QD 242 is further illustrated in FIG. 12.

The activation circuit 320 is configured or designed to activate movement of the motor 310 and to switch direction of the movement. The activation circuit 320 is controlled by the motor control circuit 340. It may receive power from the fan-out circuit 214. In one embodiment, the activation circuit 320 receives power via a power line of an interface bus such as the VBUS wire in the USB. The activation circuit 320 may include mechanical parts such as nuts, screws, tabs, or collars to cause a mechanical action on the QD when moving past it. The movement actuates the QD by pressing or sliding the tabs or collars on a mechanism on the QD. In one embodiment, the activation circuit 320 includes an H-bridge circuit that can switch the polarity of a voltage applied to the motor 310 to allow the motor 310 to move forward or backward. Controlling the motor to move forward and backward allows the motor to actuate the quick disconnect in the forward direction and then return to its home position after the disconnection in the backward or reverse direction. In addition to operating disconnection, the activation circuit 320 may also perform other tasks based on the motor motion such as self-test.

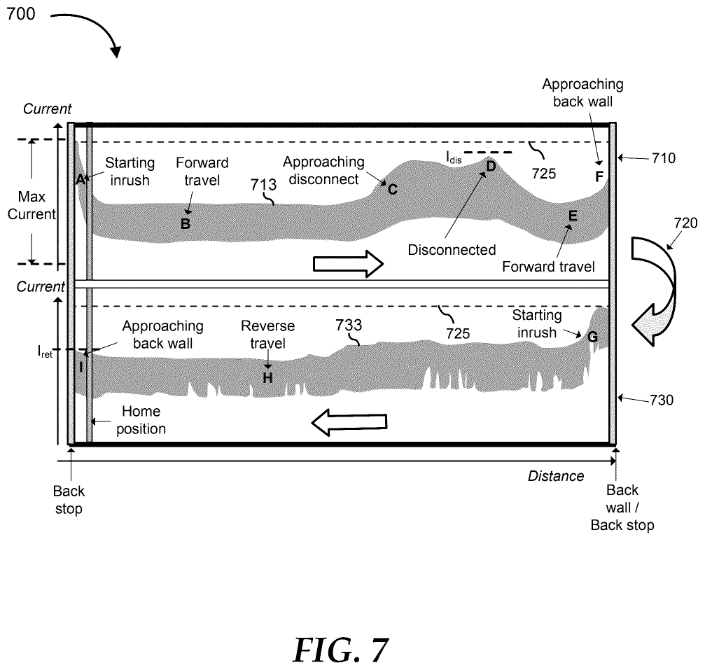

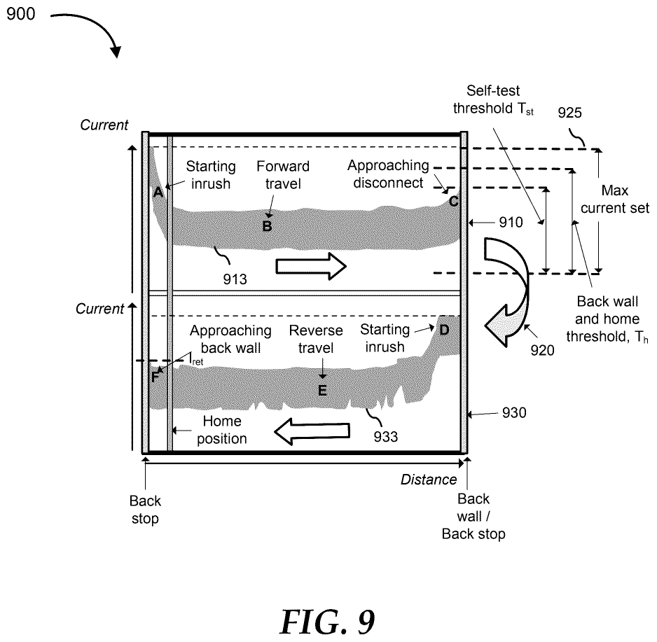

The current sensing circuit 330 is configured or designed to sense motor current as a function of the movement. The value of the current may indicate the relative position of the motor and allows inferring the state of the circuit, the QD, or the hose. For example, absence of current when there should be some amount of current may indicate an open circuit. The current sensing circuit 330 may be a separate circuit or integrated in the activation circuit 330. In one embodiment, the current sensing circuit 330 is a part of the H-bridge circuit in the activation circuit 320. There is a direct relationship between the motor movement and the motor current. Therefore, by examining the current value through the current sensing circuit, it is possible to infer the motor distance with respect to the home position. An example to illustrate this relationship is shown in FIG. 7 and similarly in FIG. 9.

The motor control circuit 340 is configured or designed to control the activation circuit based on the sensed motor current and to determine a hose state. The hose state includes an attached state and a disconnected state. The attached state is the state in which the hose is attached to the corresponding QD and is in the cooling loop. The disconnected state is the state in which the hose is disconnected from the corresponding QD and is not in the cooling loop. The motor control circuit 340 may be implemented by a microcontroller that can execute a program from an onboard memory. The microcontroller may carry out other communication tasks such as exchanging information with the first administration circuit 216 (shown in FIG. 2) via the fan-out circuit 214. In one embodiment, the information exchange is done via a bus interface such as USB. Typical information exchanges include commands from the first administration circuit 216 via the fan-out circuit 214 to the microcontroller and status data from the microcontroller to the first administration circuit 216 via the fan-out circuit 214.

Since the motor circuit 212 is typically mounted on a respective QD, the motor control circuit 340 can only have information within its locality, namely the individual QD or hose that it is coupled with. It does not have global information of the entire rack server 110. Therefore, it has to rely on the first administration circuit 216 or the second administration circuit 226 to provide commands on what to do. Through the fan-out circuit 214, the centralized administrator 210 and the management appliance 220 can have a global view of all the N QD 242ₖ's, N QD 244ₖ's (when they are used), N hoses 232ₖ's, and N hoses 234ₖ's in the entire rack server 110 and therefore can make intelligent decisions based on the underlying cooling policy.

FIG. 4 is a diagram illustrating the fan-out circuit 214 according to an embodiment of the present disclosure. The fan-out circuit 214 may include an input/output (IO) interface 410 and a multiport hub circuit 420.

The IO interface 410 provides an interface to an IO channel of the first administration circuit 216. In one embodiment, the IO interface 410 is the USB having the VBUS line. The multiport hub circuit 420 is configured or designed to spread out signals from the IO interface 410 to the N motor circuits 212ₖ's. In essence, the multiport hub circuit 420 brings the set of interface signals at the IO interface 410 to N sets of signals that are connected to N motor circuits 212ₖ's via general-purpose input/output (GPIO) lines. In one embodiment, the multiport hub circuit 420 includes a selection circuit 425 that is configured to select the N motor circuits 212ₖ's for communication based on a daisy-chain order in a serial manner. The selection may be considered as a polling procedure where the N motor circuits 212ₖ's are addressed one at a time according to a predefined priority or order. This polling mechanism allows a fan-out of the IO channel to N IO channels that are spread over the entire rack server 116. The result is an efficient use of space and resources. Since the operations of the motor circuits are mechanical with a low speed compared to electronic responses, a polling procedure in a serial fashion is more than sufficient to accommodate the motor control actions. In addition, the daisy-chain order allows scalability and easy expansion. New motor circuits can be simply added by adding additional GPIO lines.

Power lines such as VBUS line on USB may be part of the signals from the IO interface 410 to the N motor circuits 212ₖ's. For each of the N motor circuits 212ₖ's, a pair of VBUS lines may be connected to the GPIO lines at the outputs of the multiport hub circuit 420. To provide further control to the VBUS line, a USB VBUS switch circuit may be added to each pair of the VBUS lines.

FIG. 5 is a diagram illustrating the first administration circuit 216 according to an embodiment of the present disclosure. The first administration circuit 216 may include a receiving circuit 510, an input/output (IO) channel 520, an interface management circuit 530, and a central circuit 540. The first administration circuit 216 may include more or less than the above components.

The receiving circuit 510 is configured or designed to receive a leak status of the hoses 232ₖ's and 234ₖ's. A leak detector (not shown) in the rack server 110 generates an alert signal when a leak in a cooling loop is detected. The alert signal represents the leak status. In one embodiment, the leak status has two values: a normal value indicates a normal condition and a leak value indicates a leak condition. The alert signal may also include information regarding the identity of the hose that has the leak and the location of the leak. In one embodiment, the identity of the hose that has the leak may be determined separately after a leak is detected. The leak status is transmitted to the central circuit 540 so that appropriate action can be taken.

The IO channel 520 is connected to the fan-out circuit 214, the second administration circuit 226, and the hose 232/234. It provides signals for the IO bus interface such as the USB or any other suitable communication protocol. The signals at the IO channel 520 may represent the commands sent from the central circuit 540 to the N motor circuit 212k's via the fan-out circuit 214 or the status data from the N motor circuit 212k's to the central circuit 540 via the fan-out circuit 214. In addition, the signals at the IO channel 520 may also represent the information exchanged between the second administration circuit 226 and the central circuit 540. The information may include discovery information, status inquiry, inquiry response, cooling policy, and any other information relevant to the administration of the cooling policies by the centralized administrator 210 and the management appliance 220. The IO channel also includes a wire embedded in the hose 232 or 234 for identification of source and destination of the cooling liquid. The configuration of the wire in the hose 232/234 wil be described in FIG. 13.

The interface management circuit 530 is configured or designed to manage the IO channel 520. It may include circuits or components that enable or select the bus interface that communicates with the fan-out circuit 214. For example, when it is determined that the second administration circuit 226 would take over the control of the motor circuits 212k's, the interface management circuit 530 may disable the bus interface that carries information from and to the central circuit 540 and enable the bus interface that carries information from and to the second administration circuit 226. That way, the second administration circuit 226 may be allowed to access directly the motor circuits 212ₖ's.

The central circuit 540 is configured or designed to perform the first administration tasks 217 using the receiving circuit 510 and the management interface circuit530 under the first policy. The central circuit 540 may be the workhorse of the cooling server 116. It may be a processor-based system as shown in FIG. 14 or a subset of the processor-based system. It may include a processor and a memory that contains instructions or programs that, when executed by the processor, cause the processor to perform operations described in the following. These operations may include some or all of the first administration tasks 217. The central circuit 540 receives the leak status from the receiving circuit 510 and performs operations or tasks in response to the leak status. For example, when the leak status represents a detected leak in the cooling loop, the central circuit 540 performs operations on the QD that corresponds to the hose having the leak to eject the hose from the cooling loop.

The first administration task 217 may include at least one of a discovery task 552, a disconnection task 554, and a self-test task 556. These tasks may be performed according to the first policy that dictates how the administration of the cooling services is carried out. The operations of these tasks may be combined in a particular order to achieve the stated objective.

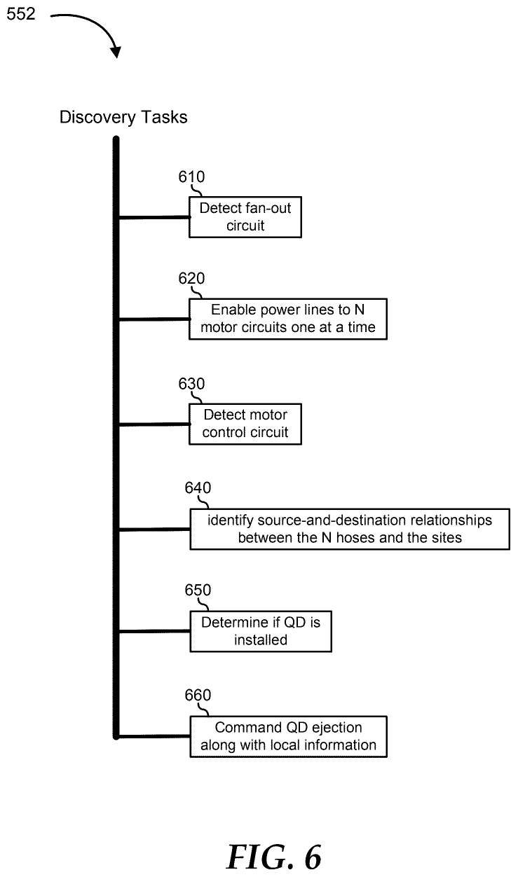

FIG. 6 is a diagram illustrating the discovery task 552 according to an embodiment of the present disclosure. The discovery task 552 may include operations 610, 620, 630, 640, 650, and 660. Each operation may correspond to a group of commands issued to the appropriate device or devices.

The operation 610 detects the presence of the fan-out circuit 214. This operation ensures the fan-out circuit 214 is present prior to executing any operation that accesses the fan-out circuit 214. The operation 610 may include a hand-shaking protocol between the central circuit 540 and the fan-out circuit 214 to ensure the fan-out circuit 214 is functional.

The operation 620 enables the power lines (e.g., VBUS line) to the N motor circuits one at a time up to the current limit. This operation powers up the motor circuit 212ₖ's during operations that involve using the motor.

The operation 630 detects the presence of the motor control circuit 340 in the motor circuit 212. In one embodiment, the motor control circuit 340 is a microcontroller which can execute a program or instructions to communicate with the central circuit 540. The operation 630 may include a handshaking protocol between the central circuit 540 and the motor control circuit 340 to ensure the motor control circuit 340 is functional.

The operation 640 identifies source-and-destination relationships between the N hoses 232ₖ's and 234ₖ's (or the respective QDs 242ₖ's and 244ₖ's) and the sites 237ₖ's. This operation determines the correspondence between a QD and the site that the hose with that QD runs through. The operation 640 allows the system to find out which hose is connected to which site in the rack server 110. While there may be N QDs and N sites, it is not always known which of the N QDs or hoses corresponds to which of the N sites. For example QD 1 may be attached to hose 1 which runs through site 7, or QD 3 may be attached to hose 3 which runs through site 6. The configuration of how the hoses run through the rack server 110 may not always be determined in advance because the arrangement may be updated or modified by maintenance personnel and it may be time consuming to manually log this information. This operation may be further explained in FIG. 13.

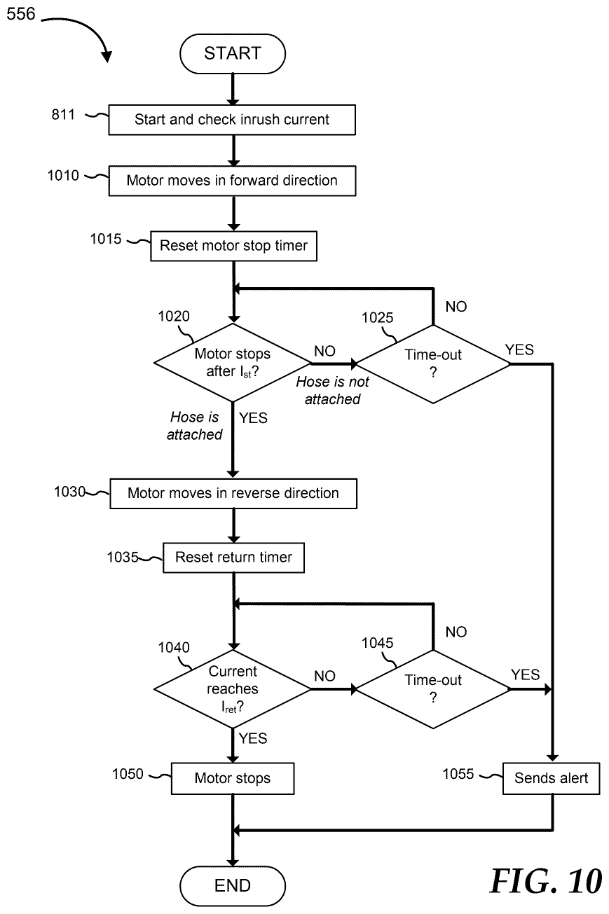

The operation 650 determines if a QD 242 or 244 is installed or attached to a hose 232 or 234, respectively. This operation may be done as part of a self-test task 556 described in FIG. 10 to ensure that all the QDs are properly installed. The operation 650 may be performed periodically or randomly according to the underlying cooling policy.

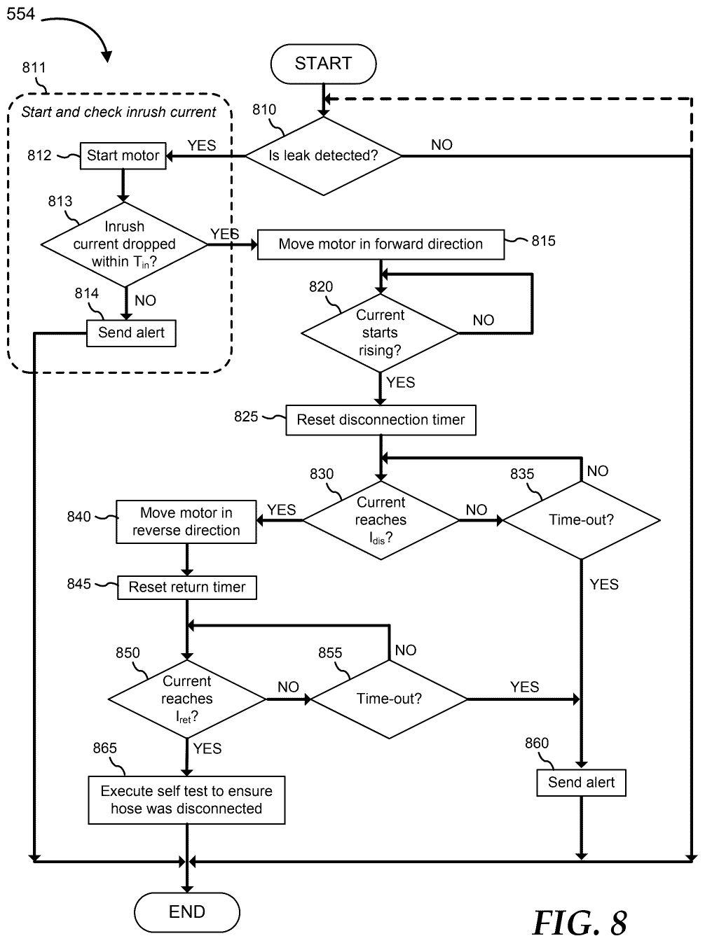

The operation 660 commands a QD ejection along with corresponding local information. This operation is performed when the leak status reports a leak as received by the receiving circuit 510. In addition to performing the disconnection, this operation sends relevant information including protection and alerts to other components in the system. The operation 660 includes the disconnection task 554 will be described in FIG. 8.

FIG. 7 is a diagram illustrating a motor movement 700 for disconnection according to an embodiment of the present disclosure. The motor movement 700 shows the motor current (the vertical axis) as a function of movement distance (the horizontal axis). By sensing the motor current, it is possible to infer the motor distance relative to the home position. The motor movement 700 has a forward direction 710 and a reverse or backward direction 730.

The forward direction 710 shows a current 713 of the motor as the motor moves in the forward direction from the back stop position to the back wall/back stop (opposite) position. The current 713 is shown as a shaded band. At a position A, the motor starts moving. The current 713 is high at inrush at a maximum current level 725 and quickly drops to a low value as the motor moves to the home position. The motor then goes through a forward travel, passing point B. As the motor approaches the QD, the current starts to rise at point C. At this point, the activation circuit begins to actuate the QD mechanism and completes the disconnection at point D. The current 713 remains high from point C to point D and the value at point D may be used as a threshold value I_{dis}. This threshold value may be used to infer the completion of the disconnection. After disconnection, the current 713 decreases and the motor continues the forward travel passing through point E. As it approaches the back wall, the current 713 increases at point F. After the motor reaches the back wall, the activation circuit switches the direction polarity to cause a reverse 720. The reverse 720 changes the direction of the motor to the reverse direction 730.

The reverse direction 730 shows a current 733 starting at the maximum current level 725 at inrush and slightly decreases through point G. As the motor continues the reverse travel through point H, the current 733 slight decreases and then remains essentially constant through the home position and point I at the back stop. The current value at point I may be used as a threshold value Iᵣₑₜ. This threshold may be used to infer the position of the motor at the back stop. The motor then stops.

The distance (or position) of the motor relative to the home position can therefore be inferred by using the previous distance (or position) and the current as measured or sensed by the current sensing circuit 330 (shown in FIG. 3). This information can also be used to determine various states of the QD or the motor circuit 212. In addition, other tasks can also be performed based on the motor current and the previous motor position. These tasks may include quick disconnection and self-test.

FIG. 8 is a flowchart illustrating a process 554 to perform a quick disconnection according to an embodiment of the present disclosure. The process 554 represents the disconnection task 554 as one of the first administration tasks 217 shown in FIG. 5.

Upon START, the process 554 determines if there is a leak (Block 810). This is reported by the receiving circuit 510 (FIG. 5) which receives a leak status from a leak detector. If there is no detected leak, the process 554 may be terminated or return to block 810 to continue checking the leak status. As in most cases, the checking of a status can be carried out in a polling scheme or an interrupt scheme. If a leak has been detected (YES branch), the process 554 performs a start and check inrush current operation 811. This operation will be performed again as shown in FIG. 10. In this operation, the process 554 starts the motor (Block 812). The inrush current will start at the maximum value 725 as shown in FIG. 7 and will drop quickly through point A. The process 554 checks if the inrush current is dropped to a normal value for forward travel within a time limit Tᵢₙ (Block 813). Tᵢₙ is the time limit for the motor to move from the back stop to the home position as shown in FIG. 7.

If the inrush current is not dropped to a normal value within the time limit Tᵢₙ (NO branch at block 813), it is likely there is a malfunction or a fault. The process 554 then sends an alert to the user or a monitoring device to inform of the malfunction (Block 814) and is then terminated. Otherwise, if the inrush current is dropped to a normal value within the time limit Tᵢₙ (YES branch at block 813), the process 554 starts the disconnection by moving the motor in the forward direction as shown in FIG. 7 at point B (Block 815). During the forward travel, the process 554 may observe the current through the current sensing circuit 330 (FIG. 3) to determine if there is any abnormal behavior. In a normal condition, the current remains fairly constant, and the movement of the motor causes the mechanical activation mechanism to begin to actuate the QD.

Next, the process 554 determines if the current starts increasing (Block 820). A rise in the current indicates the disconnection has been started. If not (NO branch), the process 554 returns to block 820 to continue checking the current. Otherwise (YES branch), the process 554 resets a disconnection timer to start a time-out period (Block 825). Next, the process 554 determines if the current has reached the threshold I_{dis} (Block 830). The threshold I_{dis} represents the current value when the disconnection is completed. This corresponds to point D in FIG. 7. If not (NO branch), the process 554 determines if the time-out period of the disconnection timer has expired (Block 835). If the time-out period of the disconnection timer has not expired (NO branch), the process 554 returns to block 830 to continue checking the motor current. Otherwise, i.e., the time-out period of the disconnection timer has expired (YES branch), the process 554 sends an alert to report a possible faulty operation (Block 860).

At block 830, if the current has reached the threshold I_{dis} (YES branch), the process 554 goes to block 840. In block 840, the disconnection having been completed, the process 554 switches the direction and moves the motor in the reverse or backward direction to return to the home position. The process 554 then resets a return timer which is different from the disconnection timer because the time to return is different than the time to disconnect (Block 845). Next, the process 554 determines if the current has reached the threshold Iᵣₑₜ (Block 850). The threshold Iᵣₑₜ represents point I in FIG. 7 when the motor reaches the back stop, passing the home position. If not (NO branch), the process 554 determines if the time-out period of the return timer has expired (Block 855). If the current has reached the threshold Iᵣₑₜ, the process 554 goes to block 865. If the time-out period of the return timer has not expired (NO branch at block 855), the process 554 returns to block 850 to continue checking the motor current. Otherwise, i.e., the time-out period of the return timer has expired (YES branch at block 855), the process 554 sends an alert to report a possible faulty operation (Block 860) and is then terminated.

In block 865, it is determined that the disconnection has been completed and the motor has returned to the back stop or the home position. The process 554 next executes a self-test to ensure the hose associated with the detected leak was indeed disconnected. This operation may be optional and depends on the guidelines in the first policy.

The process 554 is then terminated.

FIG. 9 is a diagram illustrating a motor movement 900 for self-test according to an embodiment of the present disclosure. As in FIG. 7, the motor movement 900 shows the motor current as a function of movement distance. By sensing the motor current, it is possible to infer the motor distance relative to the home position. The motor movement 900 has a forward direction 910 and a reverse or backward direction 930. There are three threshold levels of the motor current: the self-test threshold Tₛₜ, the back wall and home threshold Tₕ, and the maximum current. The self-test threshold Tₛₜ is above the normal travel current and less than the disconnect current. The back wall and home threshold Tₕ is above the self-test threshold Tₛₜ and below the maximum current. Accordingly, by comparing the current level with these thresholds, it is possible to determine the position of the motor.

The forward direction 910 shows a current 913 of the motor as the motor moves in the forward direction from the back stop position to the back wall/back stop (opposite) position. The current 913 is shown as a shaded band. At a position A, the motor starts moving. The current 913 is high at inrush at a maximum current level 925, which is similar to the maximum current level 725 in FIG. 7, and quickly drops to a low value as the motor moves to the home position. The motor then goes through a forward travel, passing point B. As the motor approaches the QD, the current starts to rise at point C and moves to the back wall. After the motor reaches the back wall, the activation circuit switches the direction polarity to cause a reverse 920. The reverse 920 changes the direction of the motor to the reverse direction 930.

The reverse direction 930 shows a current 933 starting at a maximum current level 925 at inrush and slightly decreases through point D. As the motor continues the reverse travel through point E, the current 1433 slight decreases and then remains essentially constant through the home position and point F at the back stop. The motor then stops.

FIG. 10 is a flowchart illustrating a process 556 to perform a self-test according to an embodiment of the present disclosure. The process 556 represents the self-test task 556 as one of the first administration tasks 217 shown in FIG. 5.

Upon START, the process 556 performs the operation 811 (start and check inrush current) as shown in FIG. 8. If the inrush current is not dropped to a normal value within the time limit Tᵢₙ (NO branch at block 813 in FIG. 8), the process 556 sends an alert and is terminated. If the inrush current is dropped to a normal value within the time limit Tᵢₙ (YES branch at block 813 in FIG. 8), the process 556 moves the motor in the forward direction as shown in FIG. 9 at point B (Block 1010). Next, the process 556 resets a motor stop timer (Block 1015). Then, the process 556 determines if the motor stops after reaching Iₛₜ (Block 1015). If not (NO branch), the hose is not attached, and the process 556 determines if the time-out period of the motor stop timer has expired (Block 1025). If not (NO branch), the process 556 returns to block 1020 to continue checking the motor and the current. If the time-out period of the motor stop timer has expired (YES branch), the process 556 sends an alert to report a possible faulty operation (Block 1055). If the motor stops after reaching Iₛₜ (YES branch at block 1020), the process 556 switches the direction and moves the motor in the reverse or backward direction to return to the home position (Block 1030). The process 556 then resets a return timer which is different from the motor stop timer because the time to return is different than the time to stop the motor (Block 1035). Next, the process 556 determines if the current has reached the threshold Iᵣₑₜ (Block 1040). The threshold Iᵣₑₜ represents point F in FIG. 9 when the motor reaches the back stop, passing the home position. If not (NO branch), the process 556 determines if the time-out period of the return timer has expired (Block 1045). If the time-out period of the return timer has not expired (NO branch), the process 556 returns to block 1040 to continue checking the motor current. Otherwise, i.e., the time-out period of the return timer has expired (YES branch), the process 556 sends an alert to report a possible faulty operation (Block 1055) and is then terminated.

At block 1040, if the current has reached the threshold Iᵣₑₜ, the process 556 goes to block 1050. At block 1050, it is determined that the motor has returned to the back stop or the home position and the process 556 stops the motor. The process 556 is then terminated.

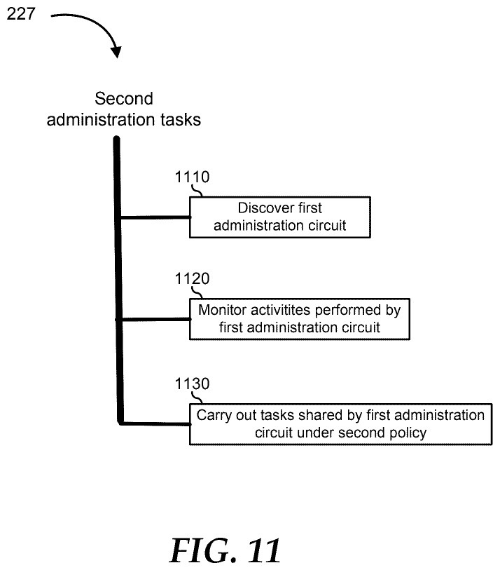

FIG. 11 is a diagram illustrating the second administration tasks 227 according to an embodiment of the present disclosure. The second administration tasks 227 may include operations 1110, 1120, and 1130. Each operation may correspond to a group of commands issued to the appropriate device or devices.

The operation 1110 discovers the first administration circuit 216 (FIG. 2). The objective of this operation is to ensure that the first administration circuit 216 is installed and functional. This operation may be performed by a handshaking protocol established between the first administration circuit 216 and the second administration circuit 226. The two circuits may exchange information via the communication interface between the two using any suitable protocol.

The operation 1120 monitors activities performed by the first administration circuit 216. This operation allows the second administration tasks 227 to collect events and observables from the first administration circuit 216 to infer the operational state or health status of the overall rack server 110. The operation 1120 may also records any relevant operations with proper time stamps to maintain an operational history. This can be done by exchanging information via any suitable communication protocol.

The operation 1130 carries out tasks that are shared by the first administration circuit 216 according to the second policy. The second policy may include guidelines for resolve contractions between the first administration circuit 216 and the second administration circuit 226. For example, the second policy may allow the second administration circuit 226 to force an ejection of a hose or override the first administration circuit 216 in operations on the QDs. The first administration circuit 216 may self-detach from the fan-out circuit 214 and float the IO channel 520 so that the second administration circuit 226 may take over. Once taking over the fan-out circuit 214, the second administration circuit 226 may issue commands to, or receive status from, the motor circuit 212ₖ's and control the respective QDs.

FIG. 12 is a diagram illustrating a combination 1200 of the motor circuit and the hose assembly according to an embodiment of the present disclosure. The combination 1200 includes the motor circuit 212, the QD 242, and the hose 232 or 234. The motor circuit 212 is as shown in FIG. 3. It includes the motor 310, the activation circuit 320, the current sensing circuit 330, and the motor control circuit 340.

The quick disconnect 242/244 is attached to the hose 232/234. The motor circuit 212 is mounted on the QD 242/244 to allow the activation circuit 320 to actuate the QD 242/244. The activation circuit 320 includes a screw 321, a nut 323, a first collar 325, and a second collar 327. Other mechanical parts, such as a bush and a block, may be used to facilitate the actuation. The screw 321 and the nut 323 are used to attached to the motor 310. The first collar 325 and the second collar 327 are configured to fittingly attach to parts of the QD. When the motor 310 is activated, the nut 323 slides a block that pushes the first collar 325 toward the second collar 327. The motion causes the QD 242/244 to actuate the disconnect mechanism.

FIG. 13 is a diagram illustrating a hose with an embedded wire according to an embodiment of the present disclosure. The hose 232/234 is configured or designed to embed a wire 1310. The embedding is designed such that it does not interfere with the normal operation of the hose, namely transporting the cooling liquid. The wire 1310 is connected to the motor control circuit 340 (e.g., a microcontroller) at one of the GPIO lines. It may also be connected to the IO channel 520.

The wire 1310 allows the first administration circuit 216 to determine the source-to-destination relationship between a hose and a motor control circuit. This can be accomplished by allowing bidirectional communication through the wire 1310. The communication may be carried out by raising a signal level through the wire 1310 and responding by another signal level. The inquiry and the response taking place over the wire 1310 provide the identity of the source and the corresponding destination.

FIG. 14 is a diagram illustrating an information handling system according to an embodiment of the present disclosure.

FIG. 14 illustrates a generalized embodiment of an information handling system that implements the first administration circuit 216 or the second administration circuit 226 shown in FIG. 2. For purpose of this disclosure an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. The term “information handling system” may refer to a processing system, a control circuit, a control processor, or any processing apparatus that processes or handles information, data, or control or status words. For example, information handling system 216/226 can be a personal computer, a laptop computer, a smart phone, a tablet device or other consumer electronic device, a network server, a network storage device, a switch router or other network communication device, or any other suitable device and may vary in size, shape, performance, functionality, and price. Further, information handling system 216/226 can include processing resources for executing machine-executable code, such as a central processing unit (CPU), a programmable logic array (PLA), an embedded device such as a System-on-a-Chip (SoC), or other control logic hardware. Information handling system 216/226 can also include one or more computer-readable medium for storing machine-executable code, such as software or data. Additional components of information handling system 216/226 can include one or more storage devices that can store machine-executable code, one or more communications ports for communicating with external devices, and various input and output (I/O) devices, such as a keyboard, a mouse, and a video display. Information handling system 216/226 can also include one or more buses operable to transmit information between the various hardware components.

Information handling system 216/226 can include devices or modules that embody one or more of the devices or modules described in this disclosure, and operates to perform one or more of the methods described in this disclosure. Information handling system 216/226 may include more or less than the components described in the following. Information handling system 216/226 includes first and second processors 1402 and 1404, an input/output (I/O) interface 1410, memories 1420 and 1425, a graphics interface 1430, a basic input and output system/universal extensible firmware interface (BIOS/UEFI) module 40, a disk controller 1450, a hard disk drive (HDD) 1454, an optical disk drive (ODD) 1456, a disk emulator 1460 connected to an external solid state drive (SSD) 1462, an I/O bridge 1470, one or more add-on resources 1474, a trusted platform module (TPM) 1476, a network interface 1480, a management device 1490, and a power supply 1495. Processors 1402 and 1404, I/O interface 1410, memory 1420, graphics interface 1430, BIOS/UEFI module 1440, disk controller 1450, HDD 1454, ODD 1456, disk emulator 1460, SSD 1462, I/O bridge 1470, add-on resources 1474, TPM 1476, and network interface 1480 operate together to provide a host environment of information handling system 216/226 that operates to provide the data processing functionality of the information handling system. The host environment operates to execute machine-executable code, including platform BIOS/UEFI code, device firmware, operating system code, applications, programs, and the like, to perform the data processing tasks associated with information handling system 216/226.

In the host environment, processor 1402 is connected to I/O interface 1410 via processor interface 1406, and processor 1404 is connected to the I/O interface via processor interface 1408. Memory 1420 is connected to processor 1402 via a memory interface 1422. Memory 1425 is connected to processor 1404 via a memory interface 1427.

Graphics interface 1430 is connected to I/O interface 1410 via a graphics interface 1432, and provides a video display output 1436 to a video display 1434. In a particular embodiment, information handling system 216/226 includes separate memories that are dedicated to each of processors 1402 and 1404 via separate memory interfaces. An example of memories 1420 and 1430 include random access memory (RAM) such as static RAM (SRAM), dynamic RAM (DRAM), non-volatile RAM (NV-RAM), or the like, read only memory (ROM), another type of memory, or a combination thereof. Processor 1402 and/or processor 1404 may process data or information to be displayed on a monitor.

BIOS/UEFI module 1440, disk controller 1450, and I/O bridge 1470 are connected to I/O interface 1410 via an I/O channel 1412. An example of I/O channel 1412 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 1410 can also include one or more other I/O interfaces, including an Industry Standard Architecture (ISA) interface, a Small Computer Serial Interface (SCSI) interface, an Inter-Integrated Circuit (I²C) interface, a System Packet Interface (SPI), a Universal Serial Bus (USB), another interface, or a combination thereof. BIOS/UEFI module 1440 includes BIOS/UEFI code operable to detect resources within information handling system 140, to provide drivers for the resources, initialize the resources, and access the resources. BIOS/UEFI module 1440 includes code that operates to detect resources within information handling system 140, to provide drivers for the resources, to initialize the resources, and to access the resources.

Disk controller 1450 includes a disk interface 1452 that connects the disk controller to HDD 1454, to ODD 1456, and to disk emulator 1460. An example of disk interface 1452 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 1460 permits SSD 1464 to be connected to information handling system 216/226 via an external interface 1462. An example of external interface 1462 includes a USB interface, an IEEE 1394 (Firewire) interface, a proprietary interface, or a combination thereof.

Alternatively, solid-state drive 1464 can be disposed within information handling system 216/226.

I/O bridge 1470 includes a peripheral interface 1472 that connects the I/O bridge to I/O port or add-on resource 1474, to TPM 1476, and to network interface 1480. Peripheral interface 1472 can be the same type of interface as I/O channel 1412, or can be a different type of interface. As such, I/O bridge 1470 extends the capacity of I/O channel 1412 where peripheral interface 1472 and the I/O channel are of the same type, and the I/O bridge translates information from a format suitable to the I/O channel to a format suitable to the peripheral channel 1472 where they are of a different type. I/O port 1474 can include a parallel or serial I/O channel, a data storage system, an additional graphics interface, a network interface card (NIC), a sound/video processing card, another add-on resource, or a combination thereof. I/O port 1474 can be on a main circuit board, on separate circuit board or add-in card disposed within information handling system 216/226, a device that is external to the information handling system, or a combination thereof.

Network interface 1480 represents a NIC disposed within information handling system 216/226, on a main circuit board of the information handling system, integrated onto another component such as I/O interface 1410, in another suitable location, or a combination thereof. Network interface device 1480 includes network channels 1482 and 1484 that provide interfaces to devices that are external to information handling system 216/226. In a particular embodiment, network channels 1482 and 1484 are of a different type than peripheral channel 1472 and network interface 1480 translates information from a format suitable to the peripheral channel to a format suitable to external devices. An example of network channels 1482 and 1484 includes InfiniBand channels, Fibre Channel channels, Gigabit Ethernet channels, proprietary channel architectures, or a combination thereof. Network channels 1482 and 1484 can be connected to external network resources (not illustrated). The network resource can include another information handling system, a data storage system, another network, a grid management system, another suitable resource, or a combination thereof.

Management device 1490 represents one or more processing devices, such as a dedicated baseboard management controller (BMC), System-on-a-Chip (SoC) device, one or more associated memory devices, one or more network interface devices, a complex programmable logic device (CPLD), and the like, that operate together to provide the management environment for information handling system 216/226. In particular, management device 1490 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 216/226, such as system cooling fans and power supplies. Management device 1490 can include a network connection to an external management system, and the management device can communicate with the management system to report status information for information handling system 216/226, to receive BIOS/UEFI or system firmware updates, or to perform other task for managing and controlling the operation of information handling system 216/226. Management device 1490 can operate off of a separate power plane from the components of the host environment so that the management device receives power to manage information handling system 216/226 where the information handling system is otherwise shut down. An example of management device 1490 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 1490 may further include associated memory devices, logic devices, security devices, or the like, as needed or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

The above-disclosed subject matter is to be considered illustrative, and not restrictive, and the appended claims are intended to cover any and all such modifications, enhancements, and other embodiments that fall within the scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. An apparatus comprising:
N motor circuits configured to control disconnection of N hoses that transport cooling liquid to sites in a computing system;
a fanout circuit configured to communicate with the N motor circuits; and
a first administration circuit configured to administer cooling services for the computing system by performing first administration tasks on the N motor circuits under a first policy via the fanout circuit based on a detected leak associated with one of the N hoses.

2. The apparatus of claim 1 further comprising:
a second administration circuit configured to communicate with the first administration circuit and perform second administration tasks under a second policy.

3. The apparatus of claim 1 wherein each of the N motor circuits comprises:
a motor to actuate a quick disconnect coupled to a hose based on a leak status;
an activation circuit to activate movement of the motor and to switch direction of the movement, the movement actuating the quick disconnect;
a current sensing circuit to sense motor current as a function of the movement; and
a motor control circuit to control the activation circuit based on the sensed motor current and to determine a hose state.

4. The apparatus of claim 1 wherein the fanout circuit comprises:
an interface to an input/output (IO) channel of the administration circuit; and
a multiport hub circuit to spread out signals from the interface to the N motor circuits.

5. The apparatus of claim 1 wherein the first administration circuit comprises:
a receiving circuit to receive a leak status;
an input/output (IO) channel connected to the fanout circuit;
a interface management circuit to manage the IO channel; and
a central circuit to perform the first administration tasks using the receiving circuit and the management interface circuit under the first policy.

6. The apparatus of claim 1 wherein the first administration tasks include at least one of a discovery task, a disconnection task, and a self-test task.

7. The apparatus of claim 7 wherein the discovery task includes at least one of: (1) detecting the fanout circuit, (2) enabling power lines to the N motor circuits one at a time, (3) detecting the motor control circuit, (4) identifying source-and-destination relationships between the N hoses and the sites, (5) determining if a QD is installed, and (6) commanding a QD ejection along with corresponding local information.

8. The apparatus of claim 7 wherein the disconnection task includes at least one of: (1) moving the motor in a forward direction, (2) actuating the quick disconnect, (3) moving the motor in a reverse direction, (4) stopping motor at home position when the sensed current reaches a threshold, and (5) determining if hose is disconnected when motor is at the home position.

9. The apparatus of claim 7 wherein the self-test task includes at least one of: (1) moving the motor in a forward direction, (2) determining if the hose is attached, (3) determining if the hose is disconnected, (4) moving the motor in a reverse direction, and (5) determining a fault condition after a time-out period.

10. The apparatus of claim 2 wherein the second administration tasks further include at least one of: (1) discovering the first administration circuit, (2) monitoring activities performed by the first administration circuit, and (3) carrying out tasks that are shared by the first administration circuit according to the second policy.

11. A method comprising:
controlling, by N motor circuits, disconnection of N hoses that transport cooling liquid to sites in a computing system;
communicating with the N motor circuits; and
administering, by a first administration circuit, cooling policies for the computing system by performing first administration tasks on the N motor circuits under a first policy via communicating with the N motor circuits based on a detected leak associated with one of the N hoses.

12. The method of claim 11 further comprising:
communicate with the first administration circuit and perform second administration tasks under a second policy.

13. The method of claim 11 wherein controlling disconnection comprises:
actuating, using a motor, a quick disconnect coupled to a hose based on a leak status;
wherein actuating comprises activating movement of the motor and switching direction of the movement;
sensing motor current as a function of the movement;
a motor control circuit to controlling activating movement based on the sensed motor current; and
determining a hose state.

14. The method of claim 11 wherein communicating with the N motor circuits comprises:
interfacing via an interface to an input/output (IO) channel of the administration circuit; and
spreading out signals from the interface to the N motor circuits.

15. The method of claim 11 wherein administering comprises:
receiving a leak status;
managing an input/output (IO) channel connected to the fanout circuit; and
performing the first administration tasks using the leak status under the first policy.

16. The method of claim 15 wherein the first administration tasks include at least one of a discovery task, a disconnection task, and a self-test task.

17. The method of claim 16 wherein the discovery task includes at least one of: (1) detecting the fanout circuit, (2) enabling power lines to the N motor circuits one at a time, (3) detecting the motor control circuit, (4) identifying source-and-destination relationships between the N hoses and the sites, (5) determining if a QD is installed, and (6) commanding a QD ejection along with corresponding local information.

18. The method of claim 16 wherein the disconnection task includes at least one of: (1) moving the motor in a forward direction, (2) actuating the quick disconnect, (3) moving the motor in a reverse direction, (4) stopping motor at home position when the sensed current reaches a threshold, and (5) determining if hose is disconnected when motor is at the home position.

19. The method of claim 16 wherein the self-test task includes at least one of: (1) moving the motor in a forward direction, (2) determining if the hose is attached, (3) determining if the hose is disconnected, (4) moving the motor in a reverse direction, and (5) determining a fault condition after a time-out period.

20. An information handling system, comprising:
N hoses that transport cooling liquid to sites in a computing system;
a leak detector to detect a leak in one of the N hoses; and
a centralized administrator comprising:
N motor circuits configured to control disconnection of the N hoses;
a fanout circuit configured to communicate with the N motor circuits; and
a first administration circuit configured to administer cooling policies for the computing system by performing first administration tasks on the N motor circuits under a first policy via the fanout circuit based on the leak detected by the leak detector.
